(19) United States
(12) Patent Application Publication
(10) Pub. No.: US 2020/0111669 A1
(43) Pub. Date: Apr. 9, 2020

(54) METHOD FOR DEPOSITING OXIDE FILM BY PEALD USING NITROGEN

(71) Applicant: ASM IP Holding B.V., Almere (NL)

(72) Inventors: Masaru Zaitsu, Kawasaki-shi (JP); Atsuki Fukazawa, Tokyo (JP); Gama Trigagema, Yokohama-shi (JP)

(21) Appl. No.: 16/152,260

(22) Filed: Oct. 4, 2018

(51) Int. Cl. H01L 21/033; C23C 16/04; C23C 16/455; C23C 16/40; H01L 21/02; H01L 21/311

(52) U.S. Cl. CPC H01L 21/0338; H01L 21/0337; C23C 16/45536; C23C 16/45553; C23C 16/401; H01L 21/02164; H01L 21/02186; H01L 21/02189; H01L 21/02183; H01L 21/02274; H01L 21/0228; H01L 21/31116; H01L 21/0332; H01L 21/0335; C23C 16/042

(57) ABSTRACT

A method of depositing an oxide film on a template for patterning in semiconductor fabrication, includes: (i) providing a template having patterned structures thereon in a reaction space; and (ii) depositing an oxide film on the template by plasma-enhanced atomic layer deposition (PEALD) using nitrogen gas as a carrier gas and also as a dilution gas, thereby entirely covering with the oxide film an exposed top surface of the template and the patterned structures.

### BACKGROUND OF THE INVENTION

### Field of the Invention

The present invention generally relates to a method of depositing an oxide film on an underlying layer by plasma-enhanced atomic layer deposition (PEALD) without substantially damaging the underlying layer.

### Description of the Related Art

Depositing a SiO₂ film by PEALD is a method which can be conducted at a low temperature of e.g., 100° C. or lower and thus enables effective deposition of a conformal film on an organic film susceptible to heat by taking advantage of the low temperature deposition. This method is applied to patterning processes such as those by spacer-defined double patterning (SDDP) or spacer-defined quadruple patterning (SDQP) (more generally referred to as “SDxP”). However, conventional PEALD for depositing a SiO₂ film uses a plasma of a mixed gas of Ar and O₂, in which a photoresist is exposed to the plasma in the beginning of deposition until the photoresist is covered by a SiO2 film, thereby causing the photoresist to be etched and making it difficult to control the patterning size in a desired range. Considering recent trends of scale miniaturization of devices and complication of a fabrication process, the above problem can no longer be ignored in processes of next generation devices. Accordingly, there is a demand for processes which enable depositing an insulation film on an underlying photoresist while suppressing etching of the photoresist as much as possible. The present inventors have conducted research to improve patterning accuracy in semiconductor fabrication.

Any discussion of problems and solutions in relation to the related art has been included in this disclosure solely for the purposes of providing a context for the present invention, and should not be taken as an admission that any or all of the discussion was known at the time the invention was made.

### SUMMARY OF THE INVENTION

Some embodiments of the present invention provide a method of suppressing a size reduction of patterns formed with an organic material (e.g., a photoresist) while depositing an insulation film thereon by reducing adverse effect (e.g., etching the organic material) by the deposition process. Conventionally, Ar has been used as a carrier gas for feeding a precursor to a reaction chamber, and a plasma of a mixture of Ar and O₂ has been used for depositing an insulation film. Some embodiments are characterized in that N₂ is used in place of Ar (wherein all Ar gas is replaced by N₂ gas). A N₂ plasma does not promote etching of a photoresist as compared with an Ar plasma, and a N₂/O₂ plasma (“/” indicates “+”) does not promote etching of a photoresist as compared with an Ar/O₂ plasma (“/” indicates “+”), and thus, by taking advantage of the above characteristics, an insulation film (or a protective film) can be deposited on a photoresist while substantially suppressing a size reduction of photoresist patterns by using a N₂ plasma or a N₂/O₂ plasma.

N₂ may be used as a carrier gas for depositing a nitride film; however, in typical embodiments, N₂ is used as a carrier gas for depositing an oxide film. In general, since a surface reaction for depositing a SiN film requires more energy than that for other films, the surface is exposed to a N₂ plasma for a relatively long period of time to form a SiN film, whereas since an O₂ plasma (or more specifically oxygen radicals) has high reactivity, a SiO₂ film can be deposited by exposing a surface to the O₂ plasma for a relatively short period of time. Accordingly, by adding O₂ to N₂ to generate simultaneously a N₂ plasma and an O₂ plasma (a N₂/O₂ plasma) and controlling a duration of exposure to the plasma for a relatively short, an oxide film can be formed even using N₂ (i.e., the exposure to the N₂/O₂ plasma is controlled in a manner that the duration is long enough to cause oxidization to form an oxide film but is short enough not to cause nitridation to form a nitride film).

Some embodiments provide a method of forming an oxide film in a process of forming an insulation film by PEALD for SDxP patterning, while suppressing a shrinkage of an underlying carbon material layer, which method is characterized by at least one of the following:

A) N₂ is used as a carrier gas for feeding a precursor to a reaction chamber, and a dry gas consists of N₂, so that no other inert gas such as Ar and He is used as a plasma-forming gas.

B) As an oxidizing gas, O₂, N₂O, NO, NO₂, CO, and/or CO₂ are/is used singly or in any combination of two or more.

C) The duration of applying RF power is 1.0 second or less, preferably as short as about 0.2 seconds.

D) RF power is as low as 100 W or less (for a 300-mm wafer when using electrodes for conductively coupled plasma, CCP, or 0.14 W/cm² or less as power density).

In some embodiments, the insulation film is constituted by SiO, TiO, ZrO, or other metal oxides wherein a precursor can be selected according to the target film.

In some embodiments, the underlying layer on which the oxide film is deposited is a photoresist or carbon hard mask, typically constituted by an organic material.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1A is a schematic representation of a PEALD (plasma-enhanced atomic layer deposition) apparatus for depositing a dielectric film usable in an embodiment of the present invention.

FIG. 1B illustrates a schematic representation of a precursor supply system using a flow-pass system (FPS) usable in an embodiment of the present invention.

FIG. 2 shows a schematic representation of ideal steps of spacer-defined double patterning (SDDP) in which a template is covered by an oxide film in (a1) and then etched to form vertical spacers in (a2), and also shows a schematic representation of conventional steps of SDDP in which a template is covered by an oxide film in (b1) and then etched to form vertical spacers in (b2).

FIG. 3 illustrates a process sequence of one cycle of PEALD according to an embodiment of the present invention, wherein the width of each column does not necessarily represent the actual time length, and a raised level of the line in each row represents an ON-state whereas a bottom level of the line in each row represents an OFF-state.

FIG. 4 is a table showing the relationship between the type of plasma gas and etched amount of photoresist according to Reference Example 1.

FIG. 5 is a table showing properties of SiO film obtained by using Ar/O₂ plasma in Comparative Example 1 and properties of SiO film obtained by using N₂/O₂ plasma in Example 1.

FIG. 6 is a graph showing the relationship between photoresist damage and the type of plasma gas used for deposition of SiO film on the photoresist in Reference Example 2.

FIG. 7 is a Fourier Transform Infrared (FTIR) spectrum of a SiO film formed in Example 2 (“a”), Example 3 (“b”), and Comparative Example 2 (“c”).

FIG. 8 is a schematic representation of pattern transfer and target etching using space defined double patterning (SDDP) according to an embodiment of the present invention.

### DETAILED DESCRIPTION OF EMBODIMENTS

In this disclosure, “gas” may include vaporized solid and/or liquid and may be constituted by a single gas or a mixture of gases, depending on the context. Likewise, an article “a” or “an” refers to a species or a genus including multiple species, depending on the context. In this disclosure, a process gas introduced to a reaction chamber through a showerhead may be comprised of, consist essentially of, or consist of a silicon- and/or meal-containing precursor and an additive gas. The additive gas may include a reactant gas for oxidizing and/or nitriding the precursor, and an inert gas (e.g., noble gas and/or nitrogen gas) for exciting the precursor, when RF power is applied to the additive gas. The inert gas may be fed to a reaction chamber as a carrier gas and/or a dilution gas. The precursor and the additive gas can be introduced as a mixed gas or separately to a reaction space. The precursor can be introduced with a carrier gas such as a rare gas. A gas other than the process gas, i.e., a gas introduced without passing through the showerhead, may be used for, e.g., sealing the reaction space, which includes a seal gas such as a rare gas. In some embodiments, the term “precursor” refers generally to a compound that participates in the chemical reaction that produces another compound, and particularly to a compound that constitutes a film matrix or a main skeleton of a film, whereas the term “reactant” refers to a compound, other than precursors, that activates a precursor, modifies a precursor, or catalyzes a reaction of a precursor, wherein the reactant may provide an element (such as N, O) to a film matrix and become a part of the film matrix, when RF power is applied. The term “inert gas” refers to a gas that excites a precursor when RF power is applied, but unlike a reactant, it substantially does not become a part of a film matrix.

In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation processes or sequence, and/or functions or purposes of the adjacent films or layers. Further, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the present disclosure where conditions and/or structures are not specified, the skilled artisan in the art can readily provide such conditions and/or structures, in view of the present disclosure, as a matter of routine experimentation.

In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods.

The embodiments will be explained with respect to preferred embodiments. However, the present invention is not limited to the preferred embodiments.

In some embodiments, a method of depositing an oxide film on a template for patterning in semiconductor fabrication, comprises: (i) providing a template having patterned structures thereon in a reaction space; and (ii) depositing an oxide film on the template by plasma-enhanced atomic layer deposition (PEALD) using nitrogen gas as a carrier gas and also as a dilution gas, thereby entirely covering with the oxide film an exposed top surface of the template and the patterned structures. A nitrogen plasma does not cause a significant plasma damage to an underlying layer, but can be used for deposition of an oxide film by PEALD by manipulating the duration of being exposed to the nitrogen plasma, RF power to generate the nitrogen plasma, etc. so as to avoid interference with oxidization of a precursor by an oxidizing gas plasma.

In some embodiments, in step (ii), the carrier gas and the dilution gas consist essentially of nitrogen gas. If a noble gas such as Ar is used as or added to the carrier gas and/or the dilution gas, the underlying layer is likely to be damaged by sputtering effect of an Ar plasma. In some embodiments, substantially, all carrier gas and all dilution gas are constituted solely by nitrogen gas. In some embodiments, at least 95%, preferably at least 97%, by volume of the carrier gas and dilution gas are constituted by nitrogen gas. In some embodiments, substantially no noble gas is supplied to the reaction space during step (ii).

In some embodiments, the carrier gas and the dilution gas each are continuously supplied to the reaction space throughout step (ii) at a flow rate of 0.5 to 5 slm, preferably 1 to 2 slm.

In some embodiments, an oxidizing gas used in step (ii) is one or more gases selected from the group consisting of O₂, N₂O, NO, NO₂, CO, and CO₂.

In some embodiments, the oxidizing gas is continuously supplied to the reaction space throughout step (ii) at a flow rate of 10 sccm to 1000 sccm, preferably 50 sccm to 500 sccm. In some embodiments, a ratio of flow rate of oxidizing gas to flow rate of carrier/dilution gas is 2/100 to 40/100, preferably about 4/100 to about 30/100.

In some embodiments, in a PEALD cycle used in step (ii), a duration of applying RF power to the reaction space is 1.0 seconds or less, preferably 0.1 to 1.0 seconds, more preferably 0.1 to 0.5 seconds.

In some embodiments, in a PEALD cycle used in step (ii), RF power applied to the reaction space is 0.14 W/cm² or less per area of a substrate on which the template is formed, preferably 0.014 to 0.14 W/cm², more preferably 0.042 to 0.14 W/cm².

In some embodiments, a precursor used in step (ii) contains silicon or a metal such as Ti, Zr, Ta, etc., so as to deposit a film constituted by SiO, TiO, ZrO, TaO, etc., i.e., the oxide film formed in step (ii) is constituted by silicon oxide or metal oxide.

In some embodiments, the patterned structures are constituted by polymer resist and/or carbon hard mask. For example, the vertical spacers can be formed using as a pre-patterned feature (mandrel) a photoresist pattern or a hard mask patterned using a photoresist. In some embodiments, the patterned structures are constituted by an organic material.

In some embodiments, the method further comprises, after step (ii): (iii) etching the oxide film-covered template to remove an unwanted portion of the oxide film and the patterned structures so as to form vertical spacers isolated from each other for use in spacer-based patterning.

In some embodiments, the spacer-based patterning is spacer-defined double patterning (SDDP), spacer-defined quadruple patterning (SDQP), spacer-defined direct patterning, or the like. The oxide film according some embodiments can be applied to various patterning processes including processes of spacer-defined multiple patterning such as those disclosed in U.S. Publication No. 2017/0316940, processes of spacer-defined double patterning such as those disclosed in U.S. Pat. No. 8,197,915, and U.S. application Ser. No. 15/489,660, filed Apr. 17, 2017, U.S. application Ser. No. 15/832,188, filed Dec. 5, 2017, and U.S. Pat. No. 8,901,016, each disclosure of which is herein incorporated by reference in its entirety.

The present invention will be explained with reference to the drawings. However, the drawings are not intended to limit thereto.

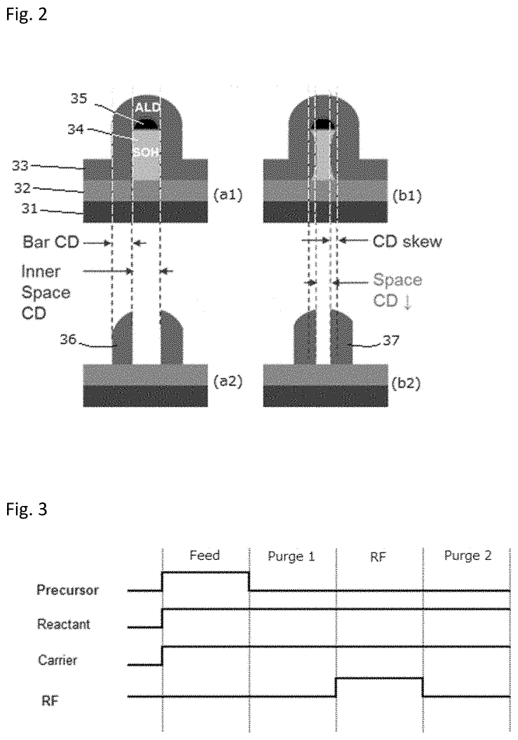

FIG. 2 shows a schematic representation of ideal steps of spacer-defined double patterning (SDDP) in which a template is covered by an oxide film in (a1) and then etched to form vertical spacers in (a2), and also shows a schematic representation of conventional steps of SDDP in which a template is covered by an oxide film in (b1) and then etched to form vertical spacers in (b2). Although there are many variations in SDDP processes, in this embodiment, as illustrated in (a1), a template 32 is formed on a target layer 31 to be etched, and on the template 32, a spin-on-hardmask (SOH) 34 has been etched in a pattern using a photoresist 35. Further, a conformal oxide film 33 is deposited on the hardmask 34 and the template 32 by atomic layer deposition (ALD) at a low temperature. The conformal oxide film 33 is then subjected to etching by anisotropic etching such as RIE (reactive ion etching) to strip the materials of the photoresist 35 and the spin-on-hardmask 34 (the materials in the core portion), thereby forming vertical spacers 36 from the conformal oxide film 33 as illustrated in (a2). In this disclosure, the term “template” refers to a film to be processed such as a film subjected to patterning or formation of holes, and the term “hardmask” refers to a film having high etch resistivity, e.g., about five times higher than a template to be etched, so that the film can effectively protect a certain portion of the template from being etched. The “hardmask” may be referred to as an “etch mask”. Thus, for example, in (a1), the template 32 is also a hardmask with reference to the target layer 31, since the template 32 will be etched in a pattern using the vertical spacers 36 in (a2) to transfer the pattern to the target layer 31.

In (a2), ideally, the bar critical dimension (Bar CD) of the vertical spacer 36 is the same as the thickness of the oxide film 33 deposited on the sidewall of the SOH 34, and the inner spacer critical dimension (Inner Space CD) is the same as the thickness of the SOH 34. However, although the oxide film is deposited by ALD at a low temperature, since the photoresist and the SOH are constituted by a carbon-based material or organic material which is easily damaged by an oxygen plasma, when an oxygen plasma is used as a reactant for depositing the oxide film, the carbon-based material or organic material is etched by the oxygen plasma while the oxide film is depositing even at a low temperature. As a result, as illustrated in (b1), the sidewall of the SOH 34 is etched by the oxygen plasma, forming concaved sidewalls. Then, when the oxide film 33 is subjected to anisotropic etching to strip the core material to form vertical spacers 37, since the thickness of the SOH is reduced along the sidewalls, the inner space CD is reduced by the amount of the sidewall of the SOH being etched, which constitutes a CD shew as illustrated in (b2). This CD change may affect the quality of a final semiconductor product. If thermal ALD is used which does not use an oxygen plasma for depositing an oxide film, theoretically, the above problem may not occur. However, such non-plasma approach (e.g., by thermal ALD using H₂O) is quite challenging and has not been fully successful. In some embodiments of the present invention, by using nitrogen gas in combination with oxygen, in place of conventional Ar in combination with oxygen, as a carrier gas (and/or a dilution gas), even when depositing an oxide film by PEALD, CD changes can be minimized.

FIG. 3 illustrates a process sequence of one cycle of PEALD according to an embodiment of the present invention, wherein the width of each column does not necessarily represent the actual time length, and a raised level of the line in each row represents an ON-state whereas a bottom level of the line in each row represents an OFF-state. As shown in FIG. 3, a reactant gas and a carrier gas are fed continuously throughout the cycle (also a dilution gas, not shown, is fed continuously throughout the cycle), whereas a precursor is fed intermittently in “Feed,” and RF power is applied intermittently in “RF,” wherein a reaction space is purged using the continuously flows of the reactant gas and carrier gas in “Purge 1” and “Purge 2”. The reactant gas is an oxidizing gas, and the carrier gas (also the dilution gas) is constituted substantially solely by nitrogen gas.

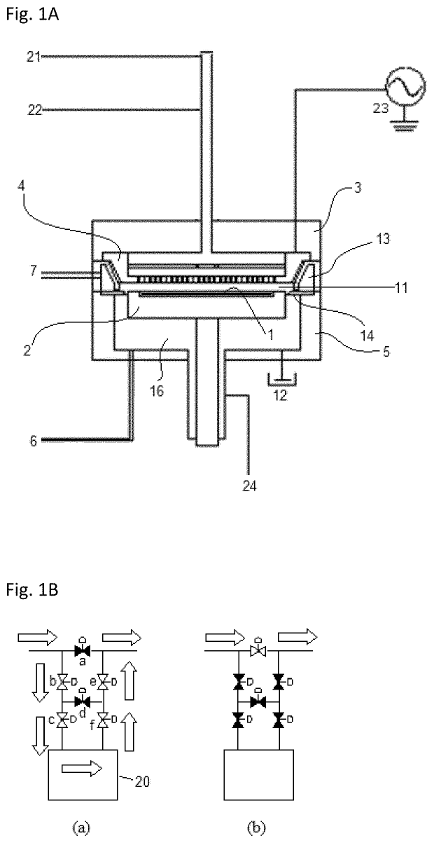

The continuous flow of the carrier gas can be accomplished using a flow-pass system (FPS) wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching the main line and the detour line. FIG. 1B illustrates a precursor supply system using a flow-pass system (FPS) according to an embodiment of the present invention (black valves indicate that the valves are closed). As shown in (a) in FIG. 1B, when feeding a precursor to a reaction chamber (not shown), first, a carrier gas such as N₂ flows through a gas line with valves b and c, and then enters a bottle (reservoir) 20. The carrier gas flows out from the bottle 20 while carrying a precursor gas in an amount corresponding to a vapor pressure inside the bottle 20, and flows through a gas line with valves f and e, and is then fed to the reaction chamber together with the precursor. In the above, valves a and d are closed. When feeding only the carrier gas (noble gas) to the reaction chamber, as shown in (b) in FIG. 1B, the carrier gas flows through the gas line with the valve a while bypassing the bottle 20. In the above, valves b, c, d, e, and f are closed.

A skilled artisan will appreciate that the apparatus includes one or more controller(s) (not shown) programmed or otherwise configured to cause the deposition and reactor cleaning processes described elsewhere herein to be conducted. The controller(s) are communicated with the various power sources, heating systems, pumps, robotics, and gas flow controllers or valves of the reactor, as will be appreciated by the skilled artisan.

In some embodiments, an oxide film can be deposited according to the sequence illustrated in FIG. 3 under conditions shown in Table 1 below.

TABLE 1
(numbers are approximate)
Conditions for PEALD

| | |
|---|---|
| Substrate temperature | 30 to 200° C. (preferably 50 to |
| | 100° C.) |
| Electrode gap (a thickness of | 3 to 30 mm (preferably 5 to 20 mm) |
| a substrate is about 0.7 mm) | |
| Pressure | 200 to 4000 Pa (preferably 300 to |
| | 1200 Pa) |
| Precursor | BDEAS, 3DMAS |
| Reactant (oxidizing gas) | O₂, N₂O, NO, NO₂, CO, CO₂ |
| Carrier gas/Dilution gas | N₂ |
| Flow rate of reactant | 10 to 1000 sccm (preferably 50 to |
| (continuous) | 500 sccm) |
| Flow rate of carrier gas | 0.5 to 5 slm (preferably 1 to 2 slm) |
| (continuous) | |
| Flow rate of dilution gas | 0 to 5 slm (preferably 0.5 to 2 slm) |
| (continuous) | |
| Flow rate of precursor | Corresponding to the flow rate of |
| | carrier gas |
| RF power (13.56 MHz) for a | 10 to 100 W (preferably 30 to |
| 300-mm wafer | 100 W) |
| Duration of “Feed” | 0.1 to 2 sec (preferably 0.2 to 1 sec) |
| Duration of “Purge 1” | 0.1 to 3 sec (preferably 0.2 to 1 sec) |
| Duration of “RF” | 0.1 to 1 sec (preferably 0.1 to 0.5 sec) |
| Duration of “Purge 2” | 0.1 to 1 sec (preferably 0.1 to 0.5 sec) |
| Duration of one cycle | 0.4 to 7 sec (preferably 0.6 to 3 sec) |
| GPC (Å/cycle) | 0.05 to 0.2 (preferably 0.1 to 0.15) |
| RI (@633 nm) | 1.42 to 1.51 (preferably 1.43 to 1.47) |
| Thickness of the film | 2 to 50 nm (preferably 3 to 20 nm) |

In this disclosure, any indicated RF power for a 300-mm wafer can be converted to W/cm² (wattage per unit area of a wafer) which can apply to a wafer having a different diameter such as 200 mm or 450 mm.

In some embodiments, the oxide film is constituted by SiO₂, TiO, HfO, ZrO, TaO, or AlO. In some embodiments, the precursor for PEALD is an alkylaminosilane. In some embodiments, the alkylaminosilane is selected from the group consisting of bisdiethylaminosilane (BDEAS), bisdimethylaminosilane (BDMAS), hexylethylaminosilane (HEAD), tetraethylaminosilane (TEAS), tert-butylaminosilane (TBAS), bistert-butylaminosilane (BTBAS), bisdimethylaminodimethylaminosilane (BDMADMS), heptamethylsilazane (HMDS), trimethysylyldiethlamine (TMSDEA), trimethylsyledimethylamine (TMSDMA), trimethyltoribinylcycletri silazane (TMTVCTS), tristrimethylhydroxyamine (TTMSHA), bisdimethylsaminomethylsilane (BDMAMS), and dimetyhlsilyldimethylamine (DMSDMA). The precursor can be constituted by a single precursor or a mixture of two or more precursors. In some embodiments, the oxide film has a conformality of 80% to 100% (typically about 90% or higher) wherein the “conformality” is determined by comparing film thickness deposited at some point (typically a middle point in a cross sectional view) on a sidewall or on a bottom of a recess to film thickness deposited on a flat surface just outside the recess.

The template having patterned structures on which the oxide film is deposited can be formed by any suitable methods including conventional methods. Typically, the thickness of the patterned structures is in a range of about 100 nm to about 500 nm, preferably, about 100 nm to about 200 nm, the distance between the patterned structures (the interval) is in a range of about 20 nm to about 200 nm, preferably, about 30 nm to about 100 nm, and the depth thereof is in a range of about 100 nm to about 500 nm, preferably, about 100 nm to about 200 nm, depending on the designed width of target trenches, the design of circuits, the fabrication processes, etc.

The oxide film-covered template can effectively be etched by any suitable methods to remove an unwanted portion of the oxide film and the patterned structures so as to form vertical spacers isolated from each other for use in spacer-based patterning, under conditions which a skilled artisan in the art can readily provide in view of the present disclosure, as a matter of routine experimentation.

In this disclosure, any indicated RF power for a 300-mm wafer can be converted to W/cm² (wattage per unit area of a wafer) which can apply to a wafer having a different diameter such as 200 mm or 450 mm.

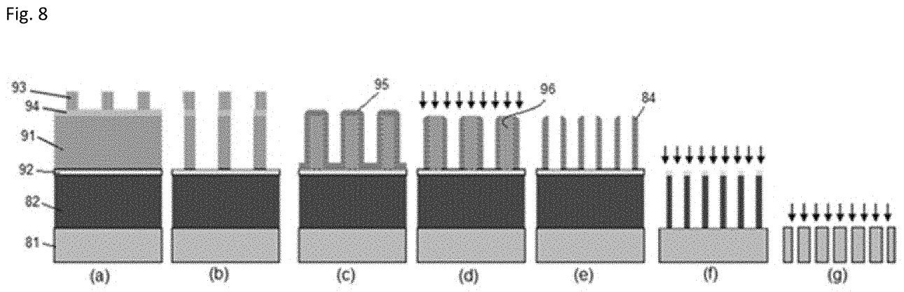

FIG. 8 is a schematic representation of pattern transfer and target etching using space defined double patterning (SDDP) according to an embodiment of the present invention, wherein the silicon/metal oxide film is used as vertical spacers to transfer a pattern from the a first template to a second template. A layer 91 is used as a first template/hardmask for increasing pattern density (e.g., pitch reduction) in SDDP processes. A second template/hardmask 82 is used for etching a target layer 81. A hardmask 92 is used for transferring a pattern from the first template/hardmask 91 to the second template/hardmask 82. In step (a) in FIG. 8, on a bottom antireflective coating (BARC) 94, a photoresist pattern 93 is formed so that the first template/hardmask 91 can be etched in the photoresist pattern in step (b) which is a step of transferring a pattern to the first template/hardmask 91. In step (c), a silicon/metal oxide film 95 is deposited by PEALD using a nitrogen/oxygen plasma according to any of the disclosed embodiments or equivalents thereto, followed by etching in step (d) which is a spacer RIE step. By stripping the material of the first template/hardmask 91 (a hardmask material in the core portions 96), vertical spacers 84 are formed in step (e). In step (f), the pattern is transferred to the second template/hardmask 82, and in step (g), the target layer 81 is subjected to dry etch. In the above, by depositing the silicon/metal oxide 95 using a nitrogen/oxygen plasma according to any of the disclosed embodiments or equivalents thereto as the vertical spacer 84, the core material 96 is not easily damaged (the sidewalls of the core material 96 are not easily etched), and thus, the pattern can be precisely be formed in the first template/hardmask 91, thereby effectively transferring the pattern from the first template/hardmask 91 to the second template/hardmask 82. In some embodiments, a planar hardmask such as the hardmask 92 may be deposited by any of the methods disclosed herein or equivalents thereof or by pulsed PECVD.

In some embodiments, alternatively, the first template/hardmask 91 is not used, and the core material 96 (which may be referred to generally as “a resist pattern”) is constituted by a photoresist material. Further, alternatively, the core material 96 is constituted by both a photoresist material and a carbon hardmask material.

It should be noted that when depositing the thin oxide layer by PEALD on the resist pattern, since PEALD generates more radicals and creates more ion bombardment than does thermal ALD or radical ALD (remote plasma), conventionally, the resist pattern surface is trimmed to a certain extent in step (c). Thus, the width of the resist pattern is reduced in step (c). The above-described phenomenon (trimming takes place while depositing) can be seen or confirmed by observing a STEM photograph of a cross section of the resist pattern or by measuring an increase of the line width in step (c) which is lower than that in the case where the same layer is deposited under the same conditions except that the layer is deposited on a chemically stable non-resist material. When step (c) is conducted as the above-discussed depositing step using a nitrogen/oxygen plasma, substantially without using other inert gas plasma such as an rare gas plasma (e.g., an Ar plasma), the trimmed quantity of the resist pattern can be substantially reduced.

These processes can be performed using any suitable apparatus including an apparatus illustrated in FIG. 1A, for example. FIG. 1A is a schematic view of a PEALD apparatus, desirably in conjunction with controls programmed to conduct the sequences described below, usable in some embodiments of the present invention. In this figure, by providing a pair of electrically conductive flat-plate electrodes 4, 2 in parallel and facing each other in the interior 11 (reaction zone) of a reaction chamber 3 for generating a conductively coupled plasma (CCP), applying HRF power (13.56 MHz or 27 MHz) 23 to one side, and electrically grounding the other side 12, a plasma is excited between the electrodes. A temperature regulator is provided in a lower stage 2 (the lower electrode), and a temperature of a substrate 1 placed thereon is kept constant at a given temperature. The upper electrode 4 serves as a shower plate as well, and reactant gas and/or dilution gas, if any, and precursor gas and etchant gas are introduced separately into the reaction chamber 3 through a gas line 21 and a gas line 22 (other gas line(s) are omitted), and through the shower plate 4, according to a given recipe set for each step. Additionally, in the reaction chamber 3, a circular duct 13 with an exhaust line 7 is provided, through which gas in the interior 11 of the reaction chamber 3 is exhausted. Additionally, a transfer chamber 5 disposed below the reaction chamber 3 is provided with a seal gas line 24 to introduce seal gas into the interior 11 of the reaction chamber 3 via the interior 16 (transfer zone) of the transfer chamber 5 wherein a separation plate 14 for separating the reaction zone and the transfer zone is provided (a gate valve through which a wafer is transferred into or from the transfer chamber 5 is omitted from this figure). The transfer chamber is also provided with an exhaust line 6.

In some embodiments, in the apparatus depicted in FIG. 1A, the system of switching flow of an inactive gas and flow of a precursor gas illustrated in FIG. 1B (described earlier) can be used to introduce the precursor gas in pulses without substantially fluctuating pressure of the reaction chamber.

In some embodiments, a dual chamber reactor (two sections or compartments for processing wafers disposed closely to each other) can be used, wherein a reactant gas and a noble gas can be supplied through a shared line whereas a precursor gas is supplied through unshared lines.

The present invention is further explained with reference to working examples below. However, the examples are not intended to limit the present invention. In the examples where conditions and/or structures are not specified, the skilled artisan in the art can readily provide such conditions and/or structures, in view of the present disclosure, as a matter of routine experimentation. Also, the numbers applied in the specific examples can be modified by a range of at least ±50% in some embodiments, and the numbers are approximate.

### EXAMPLES

### Reference Example 1

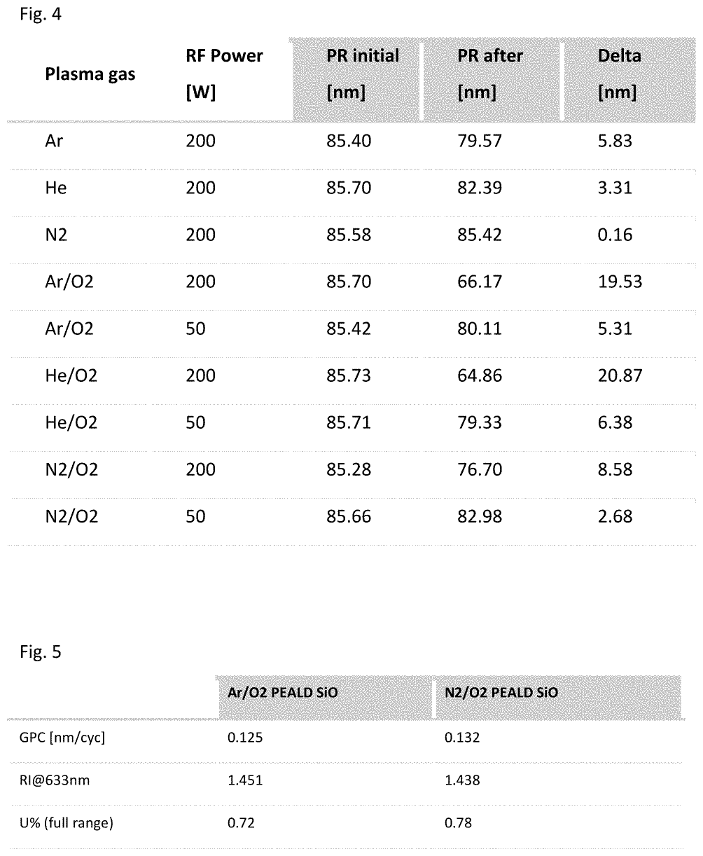

A photoresist layer (a blanket photoresist constituted by e.g., Novolacs designed for Argon Fluoride laser (ArF) lithography) was formed on a 300-mm substrate at a thickness which was considered to be an initial CD (“PR initial”) shown in FIG. 4, and then the substrate was loaded to an apparatus illustrated in FIG. 1A. The photoresist layer was exposed to a plasma using a gas shown in FIG. 4 (‘Plasma gas”) generated by applying RF power (13.56 MHz) shown in FIG. 4 (“RF Power”) under conditions shown in Table 2 below to evaluate plasma damage to the photoresist layer by measuring a reduction of the thickness of the layer after being exposed to the plasma. The results are shown in FIG. 4.

TABLE 2
(numbers are approximate)
Conditions for plasma exposure

| | |
|---|---|
| Resist material | ArF resist |
| Temperature | 75° C. |
| Pressure | 400 Pa |
| Plasma gas | See FIG. 4 |
| Plasma gas flow | Ar, He, N₂ = 2 SLM; |
| | O2 = 0.5 SLM |
| RF power for a 300-mm wafer | See FIG. 4 |
| Duration | 10 seconds |
| Electrode gap | 10 mm |

As shown in FIG. 4, although all the plasma gases induced a reduction of the thickness of the layers (see the thickness (“PR after”) after being exposed to the plasma), the reduction of the thickness (“Delta”) after exposure to the N₂ plasma was negligible, i.e., showing substantially no change, as compared with exposure to the Ae plasma and the He plasma. Further, even when the oxygen plasma was added to the N₂ plasma, the above advantageous effect was observed, i.e., exposure to the N₂/O₂ plasma induced significantly less damage to the photoresist layer than did exposure to the Ar/O₂ plasma and the He/O₂ plasma. Furthermore, by lower RF power (typically 100 W or less), the photoresist damage was further reduced.

### Reference Example 2

A silicon oxide film (a blanket film) was deposited on a 300-mm substrate by PEALD in an apparatus illustrated in FIG. 1A with a flow-pass system (FPS) illustrated in FIG. 1B under conditions shown in Table 3 below to evaluate properties of a silicon oxide film deposited using an Ar/O₂ plasma and those of a silicon oxide film deposited using a N₂/O₂ plasma. The results are shown in FIG. 5.

TABLE 3
(numbers are approximate)
Conditions for PEALD

| | |
|---|---|
| Temperature of susceptor/ | 75° C./75° C./75° C. |
| showerhead/wall | |
| Electrode gap | 10 mm |
| Pressure | 400 Pa |
| Precursor | BDEAS |
| Reactant | O2 |
| Carrier gas/Dilution gas | Either Ar or N2 |
| Flow rate of reactant (continuous) | 500 sccm |
| Flow rate of carrier gas (continuous) | 2 slm |
| Flow rate of dilution gas (continuous) | 1 slm |
| Flow rate of precursor | Corresponding to the |
| | flow rate of carrier gas |
| RF power (13.56 MHz) for a | 50 W |
| 300-mm wafer | |
| Duration of “Feed” | 0.2 sec |
| Duration of “Purge 1” | 0.5 sec |
| Duration of “RF” | 0.4 sec |
| Duration of “Purge 2” | 0.1 sec |
| Duration of one cycle | 1.2 sec |

As shown in FIG. 5, the silicon oxide film deposited by PEALD using the N2/O2 plasma (“N2/O2 PEALD SiO”) exhibited properties similar to those of the silicon oxide film deposited by PEALD using the Ar/O2 plasma (“Ar/O2 PEALD SiO”). That is, the growth rate per cycle (“GPC”), the refractive index measured at 633 nm (“RI@633 nm”), and the film uniformity (“U%”) of the silicon oxide (“N2/O2 PEALD SiO”) were similar to those of the silicon oxide film (“Ar/O2 PEALD SiO”). The above shows that a silicon oxide film can be deposited by PEALD even when entirely replacing Ar by N2 (a bottle flow shown in FIG. 2B also need not be changed).

Additionally, silicon oxide films were deposited on substrates, respectively, under conditions substantially similar to those shown in Table 3 above. The deposited silicon oxide films were then subjected to wet etching using a dHF (500:1) solution (at a temperature of 25° C. for 180 seconds). As a result, both silicon oxide films (both “N2/O2 PEALD SiO” and “N2/O2 PEALD SiO”) exhibited a WERR (a wet etch rate relative to that of thermal oxide film) of about 20. Further, the film uniformity of both silicon oxide films remained low.

### Reference Example 3

Silicon oxide films were deposited on substrates, respectively, in a manner similar to that in Reference Example 2 under conditions shown in Table 4 blow. Thus-obtained silicon oxide films were subjected to composition analysis based on a Fourier Transform Infrared (FTIR) spectrum.

TABLE 4
(numbers are approximate)

| | Sample c | Sample a | Sample b |
|---|---|---|---|
| | O2(20%)/Ar | O2(20%)/N2 | O2(5%)/N2 |
| Precursor | BDEAS | | |
| Susceptor (° C.) | 75 | | |
| Wall (° C.) | 75 | | |
| Shower plate (° C.) | 75 | | |
| Feed/Purge/RF/Purge | 0.2/0.5/0.4/0.1 s | | |
| Power (W) | 50 | | |
| Pressure (Pa) | 400 | | |
| Gap (mm) | 10 | | |
| N2 (slm) Including | 0 | 3 | 3 |
| Carrier | | | |
| Ar (slm) Including | 3 | 0 | 0 |
| Carrier | | | |
| O2 (slm) | 0.5 | 0.5 | 0.1 |

| | |
|---|---|
| Number of cycles | 100 (~12 nm) |

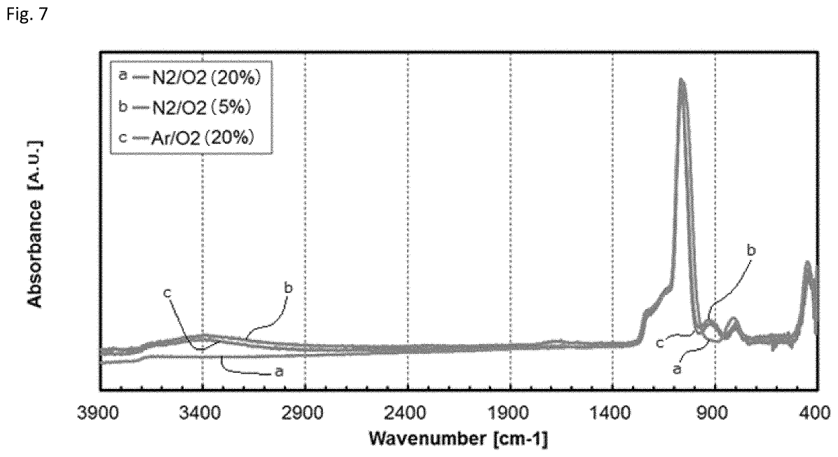

FIG. 7 is a Fourier Transform Infrared (FTIR) spectrum of a SiO film formed in sample a, sample b, and sample c. As shown in FIG. 5, all the silicon oxide films show a SiO main peak, indicating that all the films were constituted by 5i0. Samples a and b had a weak peak at about 900 cm-1 which may be attributed to the presence of impurities such as NH2 and CH2, but is not believed to indicate the presence of Si—N bonds. Further, samples a and b also had a weak peak at about 3400 cm-1 which indicates the presence of N—H bond or O—H bond, which may be attributed to moisture absorption of the films.

### Reference Example 4

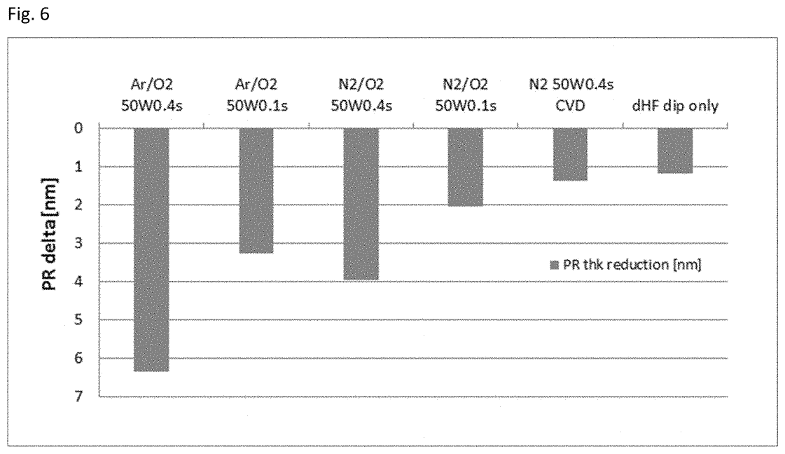

A photoresist layer (a blanket photoresist) was formed on a 300-mm substrate in a manner similar to that in Reference Example 1, and then the substrate was loaded to an apparatus illustrated in FIG. 1A wherein a silicon oxide film was deposited on the photoresist layer in a manner similar to that in Reference Example 3 except that RF power and the duration of RF power pulse are shown in FIG. 6 as “Ar/O2 50 W 0.4 s,” “Ar/O2 50W 0.1s,” “N2/O2 50 W 0.4 s,” and “N2/O2 50 W 0.1 s”. Each substrate was then subjected to wet etching using a dHF (500:1) solution (at a temperature of 25° C. for 3 minute) to evaluate plasma damage to the photoresist layer by measuring a reduction of the thickness of the layer after being exposed to the plasma, followed by wet etching. In FIG. 6, “N2 50 W 0.4 s CVD” refers to a sample wherein the substrate having the photoresist layer was exposed to a N₂ plasma (50 W, 0.4 seconds) without depositing a silicon oxide film on the photoresist layer, and “dHF dip only” refers to a sample wherein the substrate having the photoresist layer was subjected to wet etching without exposure to any plasma. The results are shown in FIG. 6.

As shown in FIG. 6, although all the plasma gases induced a reduction of the thickness of the layers after being exposed to the plasma, followed by wet etching, the reduction of the thickness (“PR delta”) after exposure to the N₂ plasma (“N2 50 W 0.4 s CVD”) was as low as that without exposure to any plasma (“dHF dip only”) (a difference of 0.2 nm or less is considered to be within a measurement error), indicating that the N₂ plasma causes substantially no damage to a carbon-based layer such as carbon hard mask and photoresist. This indicates that by using N₂ as a plasma generating gas when depositing an oxide film using an oxygen plasma, i.e., by using N₂-based plasma for depositing an oxide film as spacers on a carbon hard mask or photoresist pattern, spacers can be formed without lowering CD. The above can be substantiated by “N2/O2 50 W 0.4 s” and “N2/O2 50 W 0.1 s” which showed significantly lower reductions of the thickness than those of “Ar/O2 50 W 0.4 s” and “Ar/O2 50 W 0.1 s,” respectively. Also, as can be clear from FIG. 6, the shorter the RF duration, the lower the reduction of the thickness becomes.

### Prophetic Example 1

A 300-mm substrate with a photoresist pattern (ArF resist) is prepared by photolithography, which has a width of 50 nm, a pitch of 70 nm, and a height of 100 nm, wherein the resist pattern has a CD of <0.5 nm. A silicon oxide film is then deposited on the substrate by PEALD in an apparatus illustrated in FIG. 1A with a flow-pass system (FPS) illustrated in FIG. 1B under conditions shown in Table 5 below using an N₂/O₂ plasma so as to entirely cover the photoresist and exposed top surface of the substrate with the SiO film. The conformality of the SiO film is 95%.

TABLE 5
(numbers are approximate)
Conditions for PEALD

| | |
|---|---|
| Temperature of susceptor/ | 75° C./75° C./75° C. |
| showerhead/wall | |
| Electrode gap | 10 mm |
| Pressure | 400 Pa |
| Precursor | Bisdiethylaminosilane |
| Reactant | O₂ |
| Carrier gas/Dilution gas | N₂ |
| Flow rate of reactant (continuous) | 100 sccm |
| Flow rate of carrier gas (continuous) | 2 slm |
| Flow rate of dilution gas (continuous) | 1 slm |
| Flow rate of precursor | Corresponding to the |
| | flow rate of carrier gas |
| RF power (13.56 MHz) for a | 50 W |
| 300-mm wafer | |
| Duration of “Feed” | 0.2 sec |
| Duration of “Purge 1” | 0.5 sec |
| Duration of “RF” | 0.4 sec |
| Duration of “Purge 2” | 0.1 sec |
| Duration of one cycle | 1.2 sec |

Next, the SiO film is subjected to etching (anisotropic etching) to remove an unwanted portion of the SiO film and the photoresist so as to form vertical spacers isolated from each other under conditions shown in Table 6 below for use in spacer-based patterning.

TABLE 6
(numbers are approximate)

| | |
|---|---|
| Temperature | 60° C. |
| Pressure | 5 Pa |
| Etchant | Ar/O₂/CF₄ |
| Etchant flow | 200/50/20 sccm |
| RF power for a 300-mm wafer | 200 W |
| Duration | 20 seconds |
| Trimming rate in width direction | Substantially zero |

As a result, the vertical spacers having substantially the same CD as that of the initial photoresist pattern are obtained.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A method of depositing an oxide film on a template for patterning in semiconductor fabrication, comprising steps of:
(i) providing a template having patterned structures thereon in a reaction space; and
(ii) depositing an oxide film on the template by plasma-enhanced atomic layer deposition (PEALD) using nitrogen gas as a carrier gas and also as a dilution gas, thereby entirely covering with the oxide film an exposed top surface of the template and the patterned structures.

2. The method according to claim 1, further comprising, after step (ii), a step of:
(iii) etching the oxide film-covered template to remove an unwanted portion of the oxide film and the patterned structures so as to form vertical spacers isolated from each other for use in spacer-based patterning.

3. The method according to claim 1, wherein in step (ii), the carrier gas and the dilution gas consist essentially of nitrogen gas.

4. The method according to claim 3, wherein the carrier gas and the dilution gas each are continuously supplied to the reaction space throughout step (ii) at a flow rate of 0.5 to 5 slm.

5. The method according to claim 1, wherein substantially no noble gas is supplied to the reaction space during step (ii).

6. The method according to claim 1, wherein an oxidizing gas used in step (ii) is one or more gases selected from the group consisting of O₂, N₂O, NO, NO₂, CO, and CO₂.

7. The method according to claim 6, wherein the oxidizing gas is continuously supplied to the reaction space throughout step (ii) at a flow rate of 10 sccm to 1000 sccm.

8. The method according to claim 1, wherein a ratio of flow rate of oxidizing gas used in step (ii) to flow rate of the carrier/dilution gas used in step (ii) is about 4/100 to about 30/100.

9. The method according to claim 1, wherein in a PEALD cycle used in step (ii), a duration of applying RF power to the reaction space is 1.0 seconds or less.

10. The method according to claim 1, wherein in a PEALD cycle used in step (ii), RF power applied to the reaction space is 0.14 W/cm² or less per area of a substrate on which the template is formed.

11. The method according to claim 1, wherein a precursor used in step (ii) contains silicon or a metal.

12. The method according to claim 11, wherein the oxide film formed in step (ii) is constituted by silicon oxide or metal oxide.

13. The method according to claim 1, wherein the patterned structures are constituted by polymer resist and/or carbon hard mask.

14. The method according to claim 1, wherein the patterned structures are constituted by an organic material.

15. The method according to claim 2, wherein the spacer-based patterning is spacer-defined double patterning.
